(19) United States
(12) Patent Application Publication
(10) Pub. No.: US 2013/0328175 A1
(43) Pub. Date: Dec. 12, 2013

(54) METHOD FOR THE HYDROGEN PASSIVATION OF SEMICONDUCTOR LAYERS

(71) Applicants: Patrik Stenner, Hanau (DE); Stephan Wieber, Karlsruhe (DE); Michael Cölle, Schwanstetten (DE); Matthias Patz, Bottrop (DE); Reinhard Carius, Juelich (DE); Torsten Bronger, Aachen (DE)

(72) Inventors: Patrik Stenner, Hanau (DE); Stephan Wieber, Karlsruhe (DE); Michael Cölle, Schwanstetten (DE); Matthias Patz, Bottrop (DE); Reinhard Carius, Juelich (DE); Torsten Bronger, Aachen (DE)

(73) Assignee: Evonik Degussa GmbH, Essen (DE)

(21) Appl. No.: 13/991,261

(22) PCT Filed: Nov. 11, 2011
(86) PCT No.: PCT/EP11/69921

§ 371 Date: Aug. 19, 2013

(30) Foreign Application Priority Data
Dec. 3, 2010 (DE) 102010053214.2

(51) Int. Cl. H01L 21/30

(52) U.S. Cl. CPC H01L 21/3003
USPC 257/629; 438/475

(57) ABSTRACT

The present invention relates to a method for the hydrogen passivation of semiconductor layers, wherein the passivation is effected by using an arc plasma source, to the passivated semiconductor layers produced according to the method, and to the use thereof.

The present invention relates to a process for hydrogen passivation of semiconductor layers, to the passivated semiconductor layers producible by the process and to the use thereof.

Semiconductor layers may, depending on the production process used, have what are called dangling bonds in the semiconductor structure. However, this can worsen the semiconductor properties. For example, in the case of solar cells having semiconductor layers with dangling bonds, this can lead to a reduction in light-induced charge transfer. In order to improve the semiconductor properties, or to satisfy dangling bonds with hydrogen atoms, it is possible to introduce hydrogen into the semiconductor layer, especially after the production of the layer. This introduction of hydrogen is referred to as hydrogen passivation.

The literature describes some processes for hydrogen passivaton of semiconductor layers:

Publication EP 0 419 693 A1 describes a hydrogen passivation of silicon by a thermal treatment in a hydrogenous atmosphere. Preference is given to using temperatures of 250° C. to 500° C. The process described therein is, however, very complex in apparatus terms.

Publication U.S. Pat. No. 5,304,509 A discloses that a silicon substrate can be passivated with hydrogen by first treating the reverse side of the silicon substrate with a hydrogen ion beam and then irradiating (the front side) with electromagnetic radiation. After the treatment with the hydrogen ion beam, the implanted hydrogen ions diffuse rapidly through the substrate and then remedy the defects which have occurred after the irradiation. However, a disadvantage here is that the use of the hydrogen ion beam (produced by means of a Kaufmann source) leads to damage to the substrate surface. For this reason, the hydrogen ion beam can be employed only on the reverse side.

Publication EP 0 264 762 A1 describes a process for passivation, in which ions suitable for passivation act on an electrically conductive material, with a superimposed direct current acting on a high-frequency gas discharge plasma and serving to accelerate the ions suitable for passivation to the electrically conductive material. An advantage of this passivation process is the possibility of large-area and geometry-independent substrate treatment and the possibility of short process times, but a disadvantage is the high apparatus complexity of the process, which is attributable to features including the generation of the plasma at low pressure (reported: 7.6·10⁻⁴ Torr for hydrogen). The effect of this is that the process generally has to be performed in a closed space, and so employment of the passivation process in a continuous operation is impossible.

U.S. Pat. No. 4,343,830 A describes a process for passivation of polycrystalline silicon solar cells, in which a high-pressure hydrogen plasma (preferred pressure 760 Torr) is used. Compared to the process described in EP 0 264 762 A1, there is thus the advantage that generation of the plasma at low pressure is no longer required, but a disadvantage of the high-pressure hydrogen plasma used therein is that the apparatus complexity is very high here too, since radiofrequency generators and impedance units generally have to be used to generate the high-pressure hydrogen plasma.

U.S. Pat. No. 6,130,397 B1 describes a process, which is very complex in apparatus terms, for treatment of thin layers with a plasma generated by inductive coupling. In addition, the process described therein is unsuitable for good hydrogen passivation of semiconductor layers.

It is accordingly an object of the present invention to avoid the disadvantages of the prior art. More particularly, it is an object of the present invention to provide a process of low apparatus complexity for hydrogen passivation of semiconductor layers, which does not lead to damage to the substrate or to the semiconductor layers applied thereto, which can be employed in a continuous operation and which leads to particularly good passivation.

This object is achieved in the present context by the process according to the invention for hydrogen passivation of semiconductor layers, in which the passivation is effected by using a light arc plasma source.

As well as achieving the aforementioned objects, the process according to the invention additionally has the advantage that the process can be employed under atmospheric pressure and is very economically viable.

A process for hydrogen passivation of semiconductor layers in the context of the present invention is understood to mean a process for satisfaction of the aforementioned dangling bonds present at defect sites, in which atomic hydrogen is produced and transported to the particular defect site on the surface and within the semiconductor layer, and the atomic hydrogen then satisfies the particular dangling bond(s). Completion of hydrogen passivation is measurable, for example, for solar cells by an increase in light-induced charge transport relative to the time before passivation. In general, the hydrogen passivation can be checked by IR spectroscopy through the change in the bands of the respective semiconductor (for silicon layers: through the change in the characteristic band at 2000 cm⁻¹).

A semiconductor layer is understood to mean a layer which comprises or consists of at least one element semiconductor, preferably selected from the group consisting of Si, Ge, α-Sn, C, B, Se, Te and mixtures thereof, and/or at least one compound semiconductor, especially selected from the group consisting of IV-IV semiconductors such as SiGe, SiC, III-V semiconductors such as GaAs, GaSb, GaP, InAs, InSb, InP, InN, GaN, AlN, AlGaAs, InGaN, oxidic semiconductors such as InSnO, InO, ZnO, II-VI semiconductors such as ZnS, ZnSe, ZnTe, III-VI semiconductors such as GaS, GaSe, GaTe, InS, InSe, InTe, semiconductors such as CuInSe2, CuInGaSe2, CuInS2, CuInGaS2, and mixtures thereof.

Preferably, because this leads to particularly good hydrogen passivation of the semiconductor, the semiconductor layer to be passivated is, however, a silicon-containing layer, i.e. an essentially pure semiconductive silicon layer, a compound semiconductor layer comprising silicon among other elements, or a silicon-based layer additionally comprising dopants.

Most preferably, because particularly high passivation and hence particularly good electrical properties of the semiconductor layer can be achieved for corresponding layers by the process according to the invention, the silicon-containing semiconductor layer is a silicon-containing layer which has been produced thermally or with electromagnetic radiation essentially from liquid hydridosilanes.

The light arc plasma source for use in accordance with the invention is a source for a plasma generated by a self-sustaining gas discharge between two electrodes with sufficiently high electrical potential difference, in which the gas used comprises at least one hydrogen source. Corresponding plasmas have temperatures of ≦3000 K.

Light arc plasma sources usable with preference, since the light arc plasma is formed outside the actual reaction zone in the case thereof, and then the plasma can be directed to the surface of the substrate to be treated with relatively high flow velocity and hence rapidly, as a result of which the plasma formation is not affected by the substrate and the result is high process reliability, are those with which the plasma is generated by a high-pressure gas discharge at currents of <45 A.

A high-pressure gas discharge is preferably understood to mean a gas discharge at pressures of 0.5-8 bar, preferably 1-5 bar.

The high-pressure gas discharge is more preferably performed at currents of 0.1-44 A, preferably 1.5-3 A DC. Correspondingly produced plasmas have the advantage that they are potential-free and therefore cannot cause any damage to the surface as a result of discharge. Furthermore, there is no introduction of extraneous metal to the surface, since the substrate does not serve as an opposite pole.

The discharge takes place between two electrodes, the anode and the cathode. To achieve particularly good plasma formation, the cathode in particular may have a special configuration.

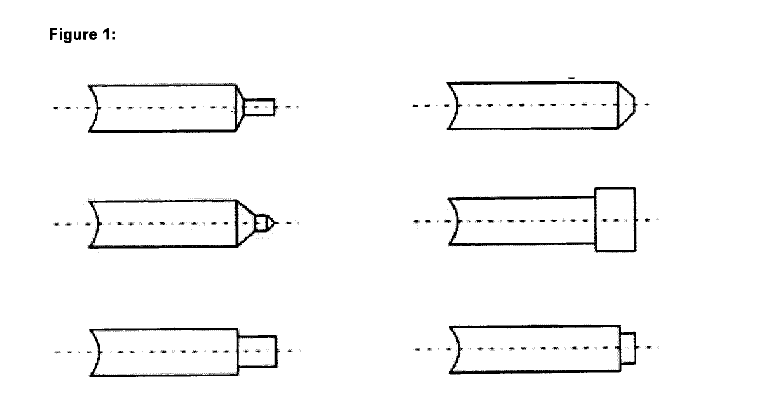

In addition, particularly low currents are used to avoid surface damage. Cathode shapes with particularly good usability at low currents are shown in FIG. 1.

The plasma generator used is preferably an indirect plasma generator, which means that the light arc exists only in the plasma generator. Corresponding indirect plasma generators have the advantage of avoiding the discharge on the substrate which occurs in the case of direct plasma generators, which can lead to surface damage to the substrate or to the semiconductor layer present thereon. Accordingly, it is advantageously possible to perform the passivation with indirect plasma generators. In the case of indirect plasma generation, the light arc generated by discharge is borne outward by a gas stream. In that case, the substrate can preferably be treated at atmospheric pressure.

Preferred plasma generators work at a rectangular voltage of 15-25 kHz, 0-400 V (preferably 260 to 300 V, especially 280 V), 2.2-3.2 A and a plasma cycle of 50-100%.

Corresponding plasmas can be generated, for example, with the light arc plasma sources available under the FG3002 generator commercial product name from Plasmatreat GmbH, Germany, or under the Plasmabeam commercial product name from Diener GmbH, Germany.

To achieve particularly good properties, the light arc plasma source in the process according to the invention is preferably used in such a way that the nozzle from which the plasma is emitted is at a distance of 50 μm to 50 mm, preferably 1 mm to 30 mm, especially preferably 3 mm to 10 mm, away from the semiconductor layer to be passivated. In the case of too short a distance, the energy density is too high, and so the surface of the substrate can be damaged. In the case of too great a distance, the plasma decays, and so only a small effect, if any, occurs.

To achieve particularly good passivation, the plasma jet leaving the nozzle is preferably directed onto the semiconductor layer present on the substrate at an angle of 5 to 90°, preferably 80 to 90°, more preferably 85 to 90° (in the latter case: essentially at right angles to the substrate surface for planar substrates).

The light arc plasma source has a nozzle from which the plasma is emitted. Suitable nozzles for the light arc plasma source are point nozzles, fan nozzles or rotary nozzles, preference being given to point nozzles which have the advantage that a higher point energy density is achieved.

Particularly good passivation is achieved, especially for the abovementioned distances of the nozzle from the semiconductor layer to be treated, when the treatment time, determined as the treated length of the semiconductor layer per unit time, is 0.1 to 500 mm/s with a treatment width of 1 to 15 mm. According to the semiconductor surface to be treated, heat treatment also accelerates the passivation. To increase the treatment rate, several plasma nozzles can be connected in series.

In a steady-state process regime, the treatment width of the plasma nozzle to achieve good passivation is preferably 0.25 to 20 mm, preferably 1 to 5 mm.

The gas used to generate the light arc plasma also has at least one hydrogen source. It has been found that, surprisingly, operation of the light arc plasma source with pure hydrogen (disadvantageous due to the automatic explosion risk in the event of ignition of the plasma) is not required. Particularly good and additionally safe hydrogen passivation can be achieved with a gas mixture comprising 0.1-5% by volume of H₂ and 99.9-95% by volume of inert gas, preferably 0.5-2% by volume of H₂ and 99.5-99% by volume of inert gas.

Inert gases used may be one or more gases which are essentially inert in relation to hydrogen, especially nitrogen, helium, neon, argon, krypton, xenon or radon. However, particularly good results are achieved when only one inert gas is used. Very particular preference is given to using argon as the inert gas.

The selection of the gases used has a direct effect on the temperature of the plasma, and thus causes a different extent of heating of the substrate and of the semiconductor layer present thereon. Since excessive heating of the substrate and of the semiconductor layer present thereon can lead to defects in the semiconductor layer, the gas mixtures used for the plasma generation are selected in combination with the further parameters for the plasma generation so as to result in plasma temperatures of 300 to 500° C., preferably 350 to 450° C.

The process according to the invention is preferably performed at atmospheric pressure.

In order to minimize the stress on the substrate and on the semiconductor layer present thereon in the course of plasma passivation, the hydrogen passivation is preferably performed in such a way that the semiconductor layer to be passivated is additionally heated in the case of use of the light arc plasma source. In principle, the heat treatment can be effected by the use of ovens, heated rollers, hotplates, infrared or microwave radiation, or the like. However, owing to the low complexity which then results, particular preference is given to performing the heat treatment with a hotplate or with heated rollers in a roll-to-roll process.

To achieve particularly good hydrogen passivation, the semiconductor layer in the case of use of the light arc plasma source is heated to temperatures of 150-500° C., preferably 200-400° C.

The process also enables simultaneous treatment of several semiconductor layers one on top of another. For example, semiconductor layers of different degrees of doping (p/n doping) or undoped semiconductor layers can be passivated by the process. The process is particularly suitable for passivation of several layers one on top of another with layer thicknesses between 10 nm and 3 μm, preference being given to layer thicknesses between 10 nm and 60 nm, 200 nm and 300 nm, and 1 μm and 2 μm.

The invention further provides the passivated semiconductor layers produced by the process according to the invention and for the use thereof for production of electronic or optoelectronic products.

The example adduced hereinafter provides further illustration of the subject-matter of the present invention, without having any limiting effect.

### EXAMPLE

An SiO₂ wafer coated by a spin-coating process using a liquid hydridosilane mixture to produce a 110 nm-thick silicon layer is heated to 400° C. on a hotplate. After the desired temperature has been attained, the wafer is treated for 30 s with a Plasmajet (FG3002 from Plasmatreat GmbH, 1.5% by volume of H2/argon, supply pressure on the plasma unit 4 bar) installed at a distance of 6 mm vertically above the wafer.

After the treatment, the wafer is taken from the hotplate and analyzed by FT-IR. The FT-IR spectra of the wafer show a rise in the peak at a wavenumber of 2000 cm⁻¹ and the decrease in the peak at 2090 cm⁻¹ for the treated wafer. This demonstrates the incorporation of hydrogen into the semiconductor.

1. A process for hydrogen passivation of a semiconductor layer, the process comprising passivating a semiconductor layer with a light arc plasma source.

2. The process according to claim 1, wherein the semiconductor layer comprises silicon.

3. The process according to claim 1, wherein the light arc plasma source generates plasma by a high-pressure gas discharge at a current of <45 A.

4. The process according to claim 3, wherein the current is from 0.1-44 A DC.

5. The process according to claim 1, wherein the light arc plasma source is an indirect plasma generator.

6. The process according to claim 1, wherein a nozzle of the light arc plasma source from which plasma emerges is at a distance of from 50 μm to 50 mm away from the semiconductor layer.

7. The process according to claim 1, wherein a plasma jet leaving a nozzle of the light arc plasma source is directed onto the semiconductor layer at an angle of from 5 to 90°.

8. The process according to claim 1, wherein a gas mixture of the light arc plasma source comprises from 0.1 to 5% by volume of H₂ and from 99.9 to 95% by volume of inert gas.

9. The process according to claim 1, further comprising heating the semiconductor layer during the passivating with the light arc plasma source.

10. A passivated semiconductor layer produced by a process comprising the process of claim 1.

11. An electronic or optoelectronic product, comprising the passivated semiconductor layer of claim 10.

12. The process of claim 4, wherein the current is from 1.5 to 3 A DC.

13. The process of claim 6, wherein the nozzle is from 1 to 30 mm away from the semiconductor layer.

14. The process of claim 7, wherein the plasma jet is directed onto the semiconductor layer at an angle of from 80 to 90°.

15. The process of claim 8, wherein the gas mixture comprises from 0.5 to 2% by volume of H₂.
